(19) United States
(12) Patent Application Publication
(10) Pub. No.: US 2007/0160447 A1
(43) Pub. Date: Jul. 12, 2007

(54) Semiconductor treating device

(75) Inventors: Norihiko Amikura, Yamanashi (JP); Kazuyuki Tezuka, Yamanashi (JP); Risako Miyoshi, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Tokyo Electron Limited, Tokyo (JP)

(21) Appl. No.: 10/588,851

(22) PCT Filed: Feb. 4, 2005
(86) PCT No.: PCT/JP05/01658

§ 371 Date: Aug. 9, 2006

(30) Foreign Application Priority Data
Feb. 26, 2004 (JP) 2004-050625

(51) Int. Cl. H01L 21/677

(52) U.S. Cl. 414/217

(57) ABSTRACT

A semiconductor treating device (1) includes treating chamber (2) connected to a common transportation chamber (8) and treating a substrate (W) to be treated. A gas supply system (40) for supplying system (40) for supplying a predetermined gas to each of the treating chambers (2) is attached to each chamber. The gas supply system (40) has a primary side connection unit (23) connected to the source of the predetermined gas and has a flow rate control unit (13). The primary side connection unit (23) connected to the source of the predetermined gas and has a flow rate control unit (13). The primary side connection unit (23) is placed on the lower side of the corresponding treating chamber (2). The flow rate control unit (13) is placed on a gas line for supplying the gas from the primary side connection unit (23) to the corresponding treating chamber (2). The flow rate control unit (13) is provided such that at least a part of it is superposed on the upper side of the primary side connection unit (23).

### FIELD OF THE INVENTION

The present invention relates to a semiconductor processing apparatus; and, more particularly, to a cluster tool type (also referred to as a multi-chamber type) processing apparatus in which a plurality of processing chambers are connected to a common transfer chamber. As used herein, the term “semiconductor processing” means a variety of processes for forming semiconductor layers, insulating layers, conductive layers and the like in a predetermined pattern on a target substrate such as a semiconductor wafer or a glass substrate for a liquid crystal display (“LCD”) or a flat panel display (“FPD”), to thereby fabricate on the target substrate semiconductor devices and other structures including wiring lines, electrodes and so forth connected to the semiconductor devices.

### BACKGROUND OF THE INVENTION

FIG. 14 is a top view schematically showing a conventional cluster tool type semiconductor processing apparatus. This processing apparatus 1 includes a normal pressure transfer system 5 that takes out a wafer W from cassettes 3 mounted on load ports 4 and transfers the wafer W under an atmospheric pressure. The processing apparatus 1 further includes a vacuum transfer system 7 connected to a transfer chamber 6 of the normal pressure transfer system 5 through load lock chambers 11 and adapted to transfer the wafer W under a predetermined vacuum pressure. Connected to around a common transfer chamber 8 of the vacuum transfer system 7 are a plurality of vacuum processing chambers 2 each of which accommodates the wafer W on a one-by-one basis and performs a process such as a chemical vapor deposition (“CVD”) or the like in a predetermined gas atmosphere.

In order to supply gases to the processing chambers 2, a gas box 50 connected to a gas source is disposed at one lateral side or a rear surface portion of the processing apparatus 2. Collectively received within the gas box 50 are flow rate control units connected to gas supply conduits 51 through which gases are supplied to the respective processing chambers 2.

In such a processing apparatus, the distance between each of the processing chambers 2 and the gas box 50, i.e., the extension length of each gas supply conduit 51, becomes long. Further, there occur mechanical differences between the processing chambers due to the fact that the extension lengths of the gas supply conduits 51 differ from each other. This may adversely affect the controllability of a pressure range, the control responsiveness and eventually the process performance. In addition, the gas box is installed on a floor independently of the processing apparatus, which increases a footprint.

Meanwhile, Japanese Patent Laid-open Publication No. 2001-156009 discloses a batch type vertical heat treatment apparatus in which a gas box is disposed at a side surface of an apparatus main body. This vertical heat treatment apparatus is distinguished from the cluster tool type processing apparatus that includes a plurality of single-wafer processing chambers.

### SUMMARY OF THE INVENTION

It is, therefore, an object of the present invention to provide a semiconductor processing apparatus capable of improving a process performance and reducing a footprint.

In accordance with a first aspect of the present invention, there is provided a semiconductor processing apparatus including:

a common transfer chamber;

a plurality of processing chambers, connected to the common transfer chamber, for processing a substrate;

a transfer mechanism, disposed within the common transfer chamber, for transferring the substrate with respect to the processing chambers; and

a plurality of gas supply systems for supplying predetermined gases, the gas supply systems being provided in the processing chambers, respectively,

wherein each of the gas supply systems includes:

a primary-side connection unit connected to gas sources of the predetermined gases, the primary-side connection unit being disposed underneath the corresponding one of the processing chambers;

a flow rate control unit for controlling flow rates of the predetermined gases, the flow rate control unit being disposed on gas lines through which the gases are supplied from the primary-side connection unit to the corresponding processing chamber, the flow rate control unit being disposed above the primary-side connection unit so as to at least partially overlap therewith; and

a gas box for enclosing the flow rate control unit, the gas box having a cover removably attached thereto for providing access to the flow rate control unit.

In accordance with a second aspect of the present invention, there is provided a semiconductor processing apparatus including:

a common transfer chamber;

a plurality of processing chambers, connected to the common transfer chamber, for processing a substrate;

a transfer mechanism, disposed within the common transfer chamber, for transferring the substrate with respect to the processing chambers; and

a plurality of gas supply systems for supplying predetermined gases, the gas supply systems being provided in the processing chambers, respectively,

wherein each of the gas supply systems includes:

a primary-side connection unit connected to gas sources of the predetermined gases, the primary-side connection unit being disposed underneath a removable floor panel of a room in which the apparatus is installed, the floor panel having a cover which is detachable for providing access to the primary-side connection unit;

a flow rate control unit for controlling flow rates of the predetermined gases, the flow rate control unit being disposed on gas lines through which the gases are supplied from the primary-side connection unit to the corresponding one of the processing chambers, the flow rate control unit being disposed under the corresponding processing chamber such that at least a part thereof lies under the corresponding processing chamber; and

a gas box for enclosing the flow rate control unit, the gas box having a cover removably attached thereto for providing access to the flow rate control unit.

### BRIEF DESCRIPTION OF THE DRAWINGS

The above and other objects and features of the present invention will become apparent from the following description of preferred embodiments, given in conjunction with the accompanying drawings, in which:

FIG. 1 is a perspective view schematically showing a semiconductor processing apparatus in accordance with a first embodiment of the present invention;

FIG. 2 is a schematic top view of the apparatus shown in FIG. 1;

FIG. 3 is a piping diagram illustrating a gas supply system employed in the apparatus shown in FIG. 1;

FIG. 4 is a side elevational view depicting a gas supply system employed in the apparatus shown in FIG. 1;

FIG. 5 is a perspective view schematically showing a gas box of the gas supply system depicted in FIG. 4;

FIG. 6 is a perspective view schematically showing a primary-side connection unit of the gas supply system depicted in FIG. 4;

FIG. 7 is a perspective view schematically showing an trunk unit of the gas supply system depicted in FIG. 4;

FIG. 8 is a perspective view schematically showing a connection structure of trunk pipelines of the gas supply system depicted in FIG. 4;

FIG. 9 is a perspective view schematically showing a semiconductor processing apparatus in accordance with a second embodiment of the present invention;

FIG. 10 is a side elevational view illustrating a flow rate control unit employed in the apparatus shown in FIG. 9;

FIG. 11 is a top view showing a primary-side connection unit employed in the apparatus shown in FIG. 9;

FIG. 12 is a side elevational view illustrating the primary-side connection unit shown in FIG. 11;

FIG. 13 is a piping diagram depicting a mechanism for concurrently closing switching valves of gas lines by a remote control operation, in a modification of the first and the second embodiment; and

FIG. 14 is a top view schematically illustrating a conventional cluster tool type semiconductor processing apparatus.

### DETAILED DESCRIPTION OF THE PREFERRED EMBODIMENTS

Hereinafter, preferred embodiments of the present invention will be described with reference to accompanying drawings. In the following description, like parts or components having substantially the same function and configuration will be designated by like reference numerals, and no duplicate description will be given unless otherwise needed.

### First Embodiment

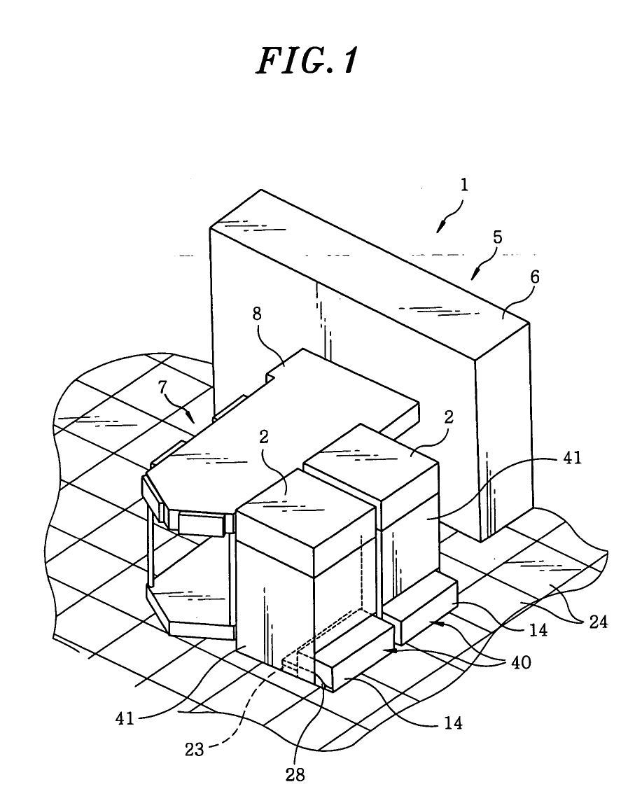

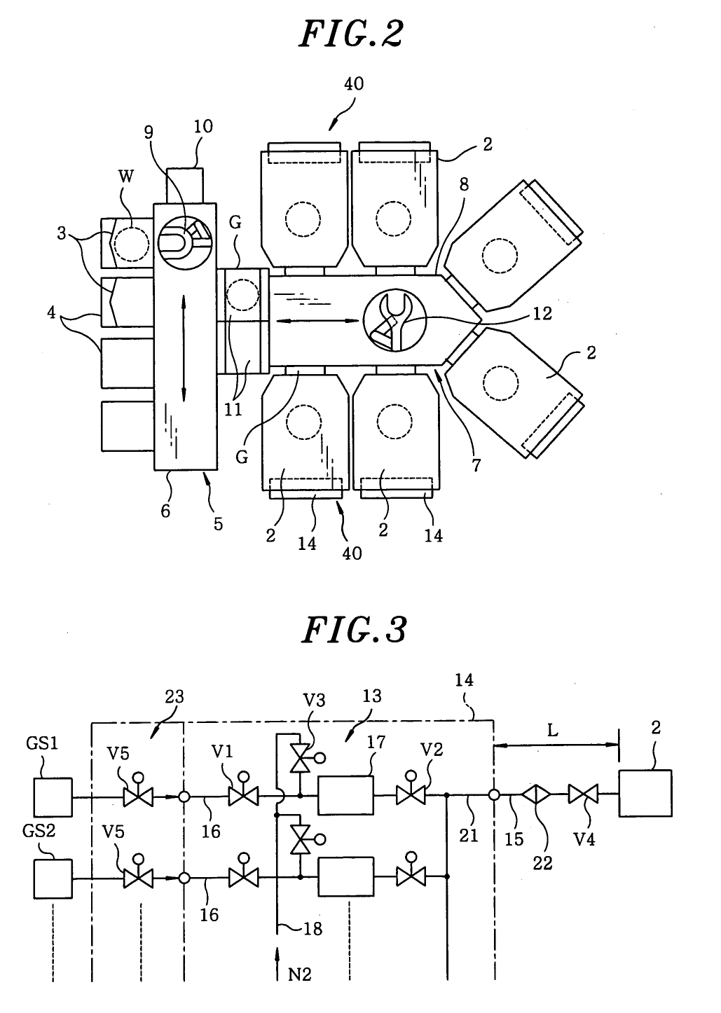

FIG. 1 is a perspective view schematically showing a semiconductor processing apparatus in accordance with a first embodiment of the present invention. FIG. 2 is a schematic top view of the apparatus shown in FIG. 1. The processing apparatus 1 is of a cluster tool type (also referred to as a multi-chamber type) wherein six processing chambers 2 are connected to around a common transfer chamber 8. The processing chambers 2 make it possible to conduct a series of processes with respect to a target substrate, e.g., a semiconductor wafer W.

More specifically, the processing apparatus 1 includes a normal pressure transfer system 5 that takes out a wafer W from cassettes 3 mounted on load ports 4 and transfers the wafer W under an atmospheric pressure. The processing apparatus 1 further includes a vacuum transfer system 7 connected to a transfer chamber 6 of the normal pressure transfer system 5 through load lock chambers 11 and adapted to transfer the wafer W under a predetermined vacuum pressure. Connected to around the common transfer chamber (vacuum transfer chamber) 8 of the vacuum transfer system 7 are a plurality of vacuum processing chambers 2 that accommodate the wafer W on a one-by-one basis and perform processes such as a chemical vapor deposition (“CVD”) and the like in a predetermined gas atmosphere.

Inside the transfer chamber 6 of the normal pressure transfer system 5, there is provided a transfer arm mechanism 9 for transferring the wafer W between the load ports 4 and the load lock chambers 11. The transfer chamber 6 is configured in an elongated shape and the transfer arm mechanism 9 is mounted for movement along a longitudinal direction of the transfer chamber 6. The plural load ports 4 are disposed at one side of the transfer chamber 6, while one ends of the load lock chambers 11 are connected to the other side of the transfer chamber 6 through respective gate valves G. At one longitudinal end of the transfer chamber 6, there is provided an orienter 10 serving to align the position of the wafer W.

Inside the transfer chamber 8 of the vacuum transfer system 7, there is disposed a transfer arm mechanism 12 for transferring the wafer W between the load lock chambers 11 and the processing chambers 2. The transfer chamber 8 is configured in an elongated shape and the transfer arm mechanism 12 is mounted for movement along a longitudinal direction of the transfer chamber 8. The other ends of the load lock chambers 11 are connected to one end of the transfer chamber 8 through respective gate valves G. Connected to the load lock chambers 11, the transfer chamber 8 and the processing chambers 2 is a vacuum generation system capable of controlling the insides thereof to a predetermined pressure. Although two load lock chambers 11 are disposed side by side in the illustrated embodiment, a single load lock chamber may be employed.

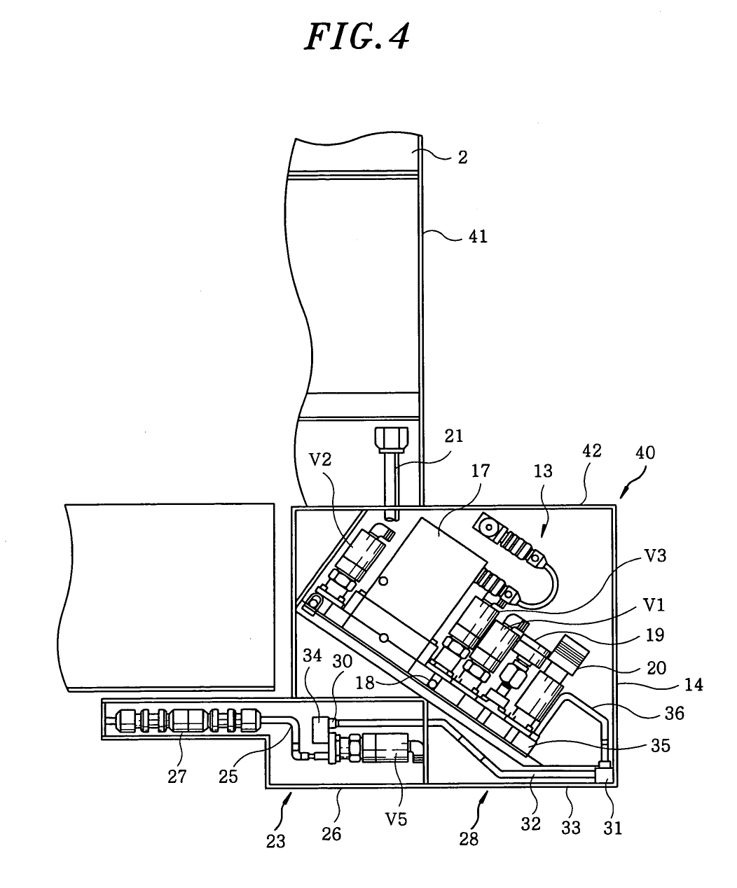

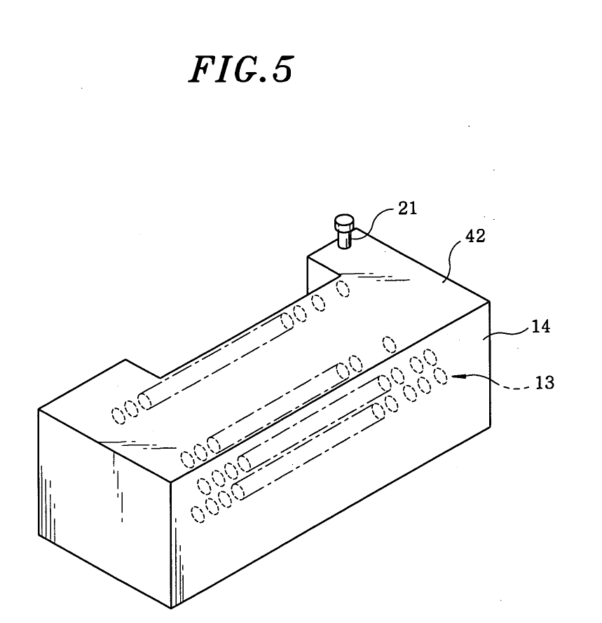

FIG. 3 is a piping diagram illustrating a gas supply system employed in the apparatus shown in FIG. 1. FIG. 4 is a side elevational view depicting the gas supply system employed in the apparatus shown in FIG. 1. FIG. 5 is a perspective view schematically showing a gas box of the gas supply system depicted in FIG. 4.

In order to supply gases to the respective processing chambers 2, the gas supply systems 40 are disposed underneath the respective processing chambers 2. Each of the gas supply system 40 is provided with gas box 14 enclosing a flow rate control unit 13 and a primary-side connection unit 23. The primary-side connection unit 23 is connected to a plurality of gas sources. Within the gas box 14, the flow rate control unit 13 is disposed on gas lines through which gases are supplied from the primary-side connection unit 23 to the corresponding processing chamber 2.

Each of the flow rate control units 13 has a plurality of pipelines 16 which are respectively connected to plural kinds of gas sources GS1, GS2 and so forth through the primary-side connection unit 23. Disposed on each of the respective pipelines 16 is a flow rate controller 17 such as a flow control system (“FCS”) (made by Fujikin Corporation, Japan) and a mass flow controller (“MFC”). The FCS is a pressure-type flow rate controller that monitors the pressure in the gas line to control the flow rate of gas. The FCS is highly sensitive to pressure variation and enjoys a broadened control range at the time when a secondary-side pressure becomes low. For these reasons, the FCS is suitable for a pipeline of short length and is cost-effective.

Valves V1 and V2 are disposed on each of the pipelines 16 at upstream and downstream sides of the flow rate controller 17. A pipeline 18 for supplying a nonreactive purge gas, e.g., N₂ gas, is connected to between the upstream side valve V1 and the flow rate controller 17 through a valve V3. Although not shown in FIG. 3, a pressure indicator 19 and a regulator 20 (not required in the FCS) are disposed at the upstream side of the valve V1. Each of the valves V1, V2 and V3 is, for example, a pneumatically operated valve (air operation valve). The flow rate controller 17, the valves V1 to V3, the pressure indicator 19 and the regulator 20 on each pipeline 16 are all installed on the top surface of the flow rate control unit 13 in view of the maintenance thereof.

The downstream sides of the respective pipelines 16 are connected to a common outlet conduit 21, which in turn is detachably connected to a gas supply conduit 15 leading to the corresponding one of the processing chambers 2. Namely, the flow rate controllers 17 provided in one-to-one relationship with plural kinds of gases are connected to the corresponding processing chamber 2 by way of the common conduits 21 and 15. A filter 22 and a valve V4 are disposed on the gas supply conduit 15.

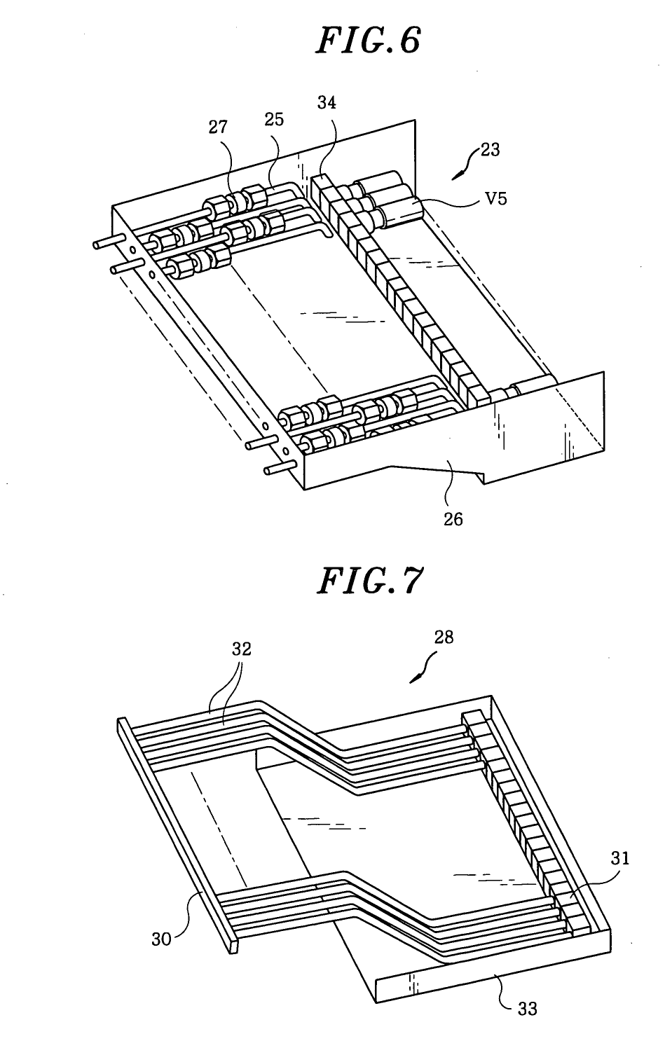

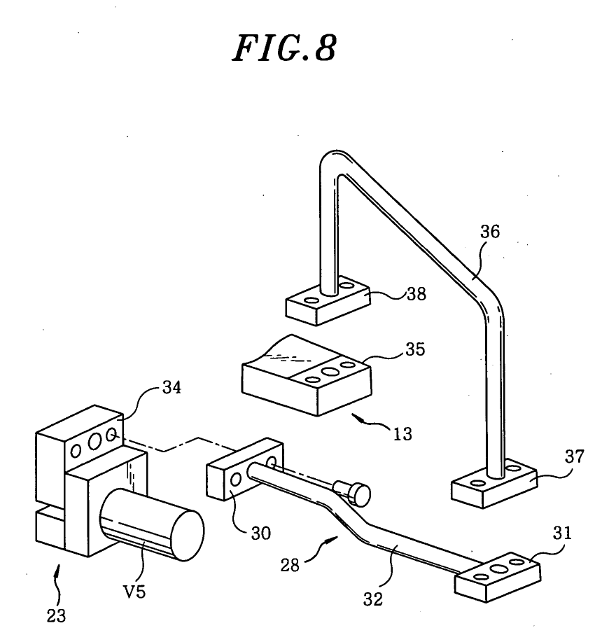

FIG. 6 is a perspective view schematically showing the primary-side connection unit 23 of the gas supply system 40 depicted in FIG. 4. FIG. 7 is a perspective view schematically showing a trunk unit 28 of the gas supply system 40 depicted in FIG. 4. FIG. 8 is a perspective view schematically showing a connection structure of trunk pipelines of the gas supply system 40 depicted in FIG. 4.

The primary-side connection unit (also referred to as a template) 23 is provided on the floor of a clean room, in which the processing apparatus 1 is installed, in such a manner that it is located just below the corresponding processing chamber 2. Before the processing apparatus 1 is installed in the clean room, the primary-side connection unit 23 is mounted on the floor of the clean room in advance through plumbing works. The floor of the clean room is constructed by fitting together a plural number of floor panels (also referred to as grating panels) 24.

As illustrated in FIG. 6, the primary-side connection unit 23 includes a plurality of pipelines 25 and a case 26 enclosing the pipelines 25. A filter 27 and a valve V5 are disposed on each of the pipelines 25. The valve V5 is, for example, a pneumatically operated valve (air operation valve). The primary-side connection unit 23 is connected to the flow rate control unit 13 through a trunk unit (also referred to as a connection unit) 28 in which trunk pipelines are gathered together.

Referring to FIG. 7, the trunk unit 28 includes a plurality of pipelines 32 each having connection portions 30 and 31 at opposite ends, and a case 33 enclosing the pipelines 32. The trunk unit 28 is disposed in front of the primary-side connection unit 23 and underneath the flow rate control unit 13. As depicted in FIG. 8, one connection portion 30 of each of the pipelines 32 is connected to a pipeline connection portion 34 of the primary-side connection unit 23. The other connection portion 31 of each of the pipelines 32 is connected to a pipeline connection portion 35 of the flow rate control unit 13 through an auxiliary pipeline 36, which has connection portions 37 and 38 at the opposite ends thereof, respectively.

Referring back to FIG. 4, the gas box 14 is removably attached to the cases 26 and 33 and cooperates therewith to hermetically enclose internal components such as the primary-side connection unit 23, the flow rate control unit 13 and the trunk unit 28. This prevents any gas from being leaked out of the gas box 14. The gas box 14 is installed such that the rear part thereof lies under the plan view contour of the corresponding processing chamber 2. Disposed underneath the processing chamber 2 is a housing 41 that accommodates a power supply unit (not shown) and the like. The rear half part of the gas box 14 is inserted in the housing 41 by, e.g., about 140 mm. This helps to reduce the footprint of the processing apparatus 1.

The flow rate control unit 13 is disposed above the primary-side connection unit 23 so as to at least partially overlap with the latter. In other words, the flow rate control unit 13 is positioned inclined downwardly from the inner portion located above the primary-side connection unit 23 (the position of the valve V2 in FIG. 4) toward the outer portion located in front of the primary-side connection unit 23 (the position of the regulator 20 in FIG. 4). The outer portion of the flow rate control unit 13 protrudes outwardly beyond the plan view contour of the corresponding processing chamber 2.

In the meantime, a removably attached cover 42 defines the front and the top surface of the gas box 14. Normally, the interior of the gas box 14 remains hidden by the housing 41 and therefore is not visible. Removal of the cover 41 enables an operator to readily gain access to the valves V1 to V3 and other components disposed on the top surface of the flow rate control unit 13. This helps to improve the maintainability of the flow rate control unit 13.

Among the six processing chambers 2, the processing chambers for performing a same process are configured to have a substantially same specification. Further, the gas supply systems 40 installed for the processing chambers 2 of the same specification are designed to have a substantially same specification. Moreover, the distance between the flow rate control unit 13 and the corresponding processing chamber 2 is set to be equal in the respective gas supply systems 40 of the same specification.

The cluster tool type semiconductor processing apparatus 1 in accordance with the present embodiment provides the following advantageous effects. Namely, since the gas boxes 14 of the gas supply systems 40 are disposed underneath the respective processing chambers 2 in a one-to-one relationship, it becomes possible to shorten the distance (pipeline length) L between the processing chamber 2 and the corresponding gas box 14. This reduces a pressure loss, thus making possible to draw down the pressure at which the gas is supplied. Furthermore, by making the lengths L of the pipelines equal, it is possible to eliminate the mechanical difference between the processing chambers 2 that perform the same process.

According to an experiment, it took about 1.0 second to reach an average pressure in the pipelines when the pipeline length L is about 7,000 mm under the condition that the pipelines have a diameter of ½ inches and the total gas flow rate is equal to 1,200 sccm. In contrast, at the time when the pipeline length L is reduced to about 4,000 mm, it took about 0.6 second to reach the average pressure, which proved the improvement of responsiveness.

The following advantages are attainable in case the FCS (pressure type flow rate controller) is used as the flow rate controllers 17. Specifically, the pressure type flow rate controller uses the principle that, when the upstream side pressure P1 and the downstream side pressure P2 of a built-in orifice satisfy the relationship of P1≧2×P2, the flow rate is proportional to the upstream side pressure P1. Accordingly, as the downstream side pressure P2 is set to a smaller value, the upstream side pressure P1 can be set within a wider range and, therefore, the flow rate control range becomes larger. By shortening the pipeline length L as in this embodiment, the downstream side pressure P2 can be reduced, so that it is possible to broaden the permissible range (control range) of the upstream side pressure P1 if the FCS (pressure type flow rate controller) is selected as the flow rate controller 17. On the contrary, the flow rate control range cannot be broadened in case of a MFC (mass flow controller). Further, measurement error may probably occur if a typical MFC is inclined as illustrated in FIG. 4, whereas no such problem takes place in the pressure type flow rate controller. In addition, although the MFC requires use of the regulator 20 to maintain the upstream side pressure constant, no regulator is needed in the pressure type flow rate controller.

The primary-side connection unit 23 connected to the gas sources is installed on the floor and underneath the respective processing chambers 2. The flow rate control unit 13 is disposed above the primary-side connection unit 23 so as to at least partially overlap with the latter. The flow rate control unit 13 and the primary-side connection unit 23 are connected to each other through the trunk unit 28 having the trunk pipelines gathered together. The gas box 14 enclosing these units 13, 23 and 28 is installed such that the rear part thereof lies under the plan view contour of the processing chamber 2. This helps to make the gas supply system 40 compact in structure, thus reducing the footprint of the processing apparatus.

Within the gas box 14, the flow rate control unit 13 is disposed to be inclined between the corresponding processing chamber 2 and the primary-side connection unit 23. Further, the cover 42 is removably attached to the gas box 14 to define the front and the top surface of the latter. This helps to improve the maintainability for the flow rate control unit 13 within the gas box 14.

### Second Embodiment

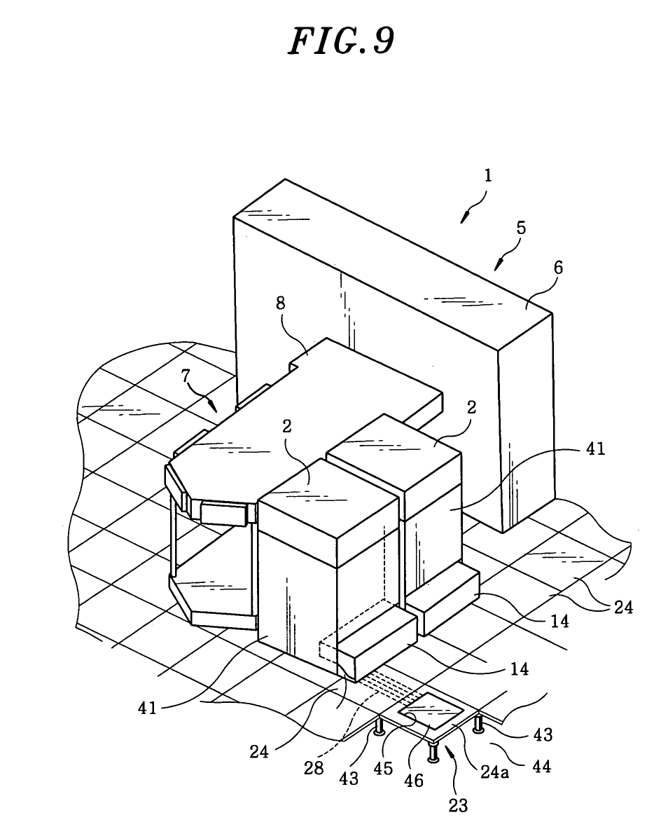

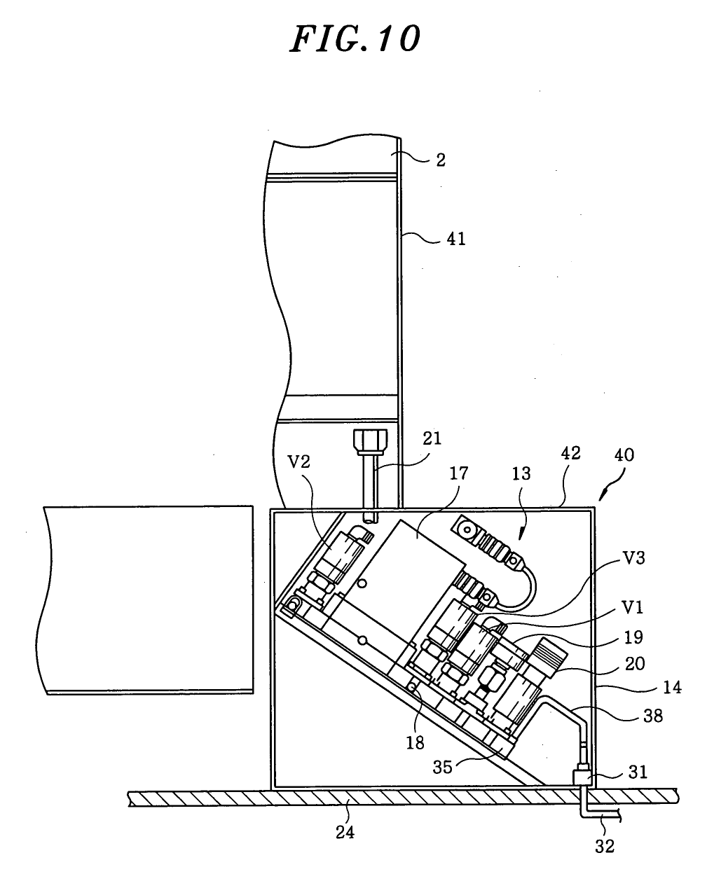

FIG. 9 is a perspective view schematically showing a semiconductor processing apparatus in accordance with a second embodiment of the present invention. FIG. 10 is a side elevational view illustrating a flow rate control unit employed in the apparatus shown in FIG. 9.

In the first embodiment set forth above, the primary-side connection unit 23 is installed on the floor and underneath the corresponding processing chamber 2 and the flow rate control unit 13 is disposed above the primary-side connection unit 23 so as to overlap with the latter. In contrast, in the second embodiment, the primary-side connection unit 23 is installed beneath a removable floor panel 24a of a clean room in which the processing apparatus 1 is placed. The floor panel 24a is provided with a detachable cover 46 that, when detached, allows an operator to gain access to the primary-side connection unit 23.

In order to supply gases to the respective processing chambers 2, the flow rate control unit 13 of the gas supply system 40 is disposed underneath each of the processing chambers 2. The flow rate control unit 13 is structurally the same as that of the first embodiment and hermetically enclosed within the gas box 14 in the same manner as described above with regard to the first embodiment. Unlike the first embodiment, however, the flow rate control unit 13 is connected to the primary-side connection unit 23 of the gas supply system 40 through trunk pipelines 32 which extend to below the floor of the clean room. The floor panel 24a to which the primary-side connection unit 23 is attached is not disposed immediately below the corresponding processing chamber 2 but placed at a position somewhat distant from the processing chamber 2 in view of the accessibility thereto.

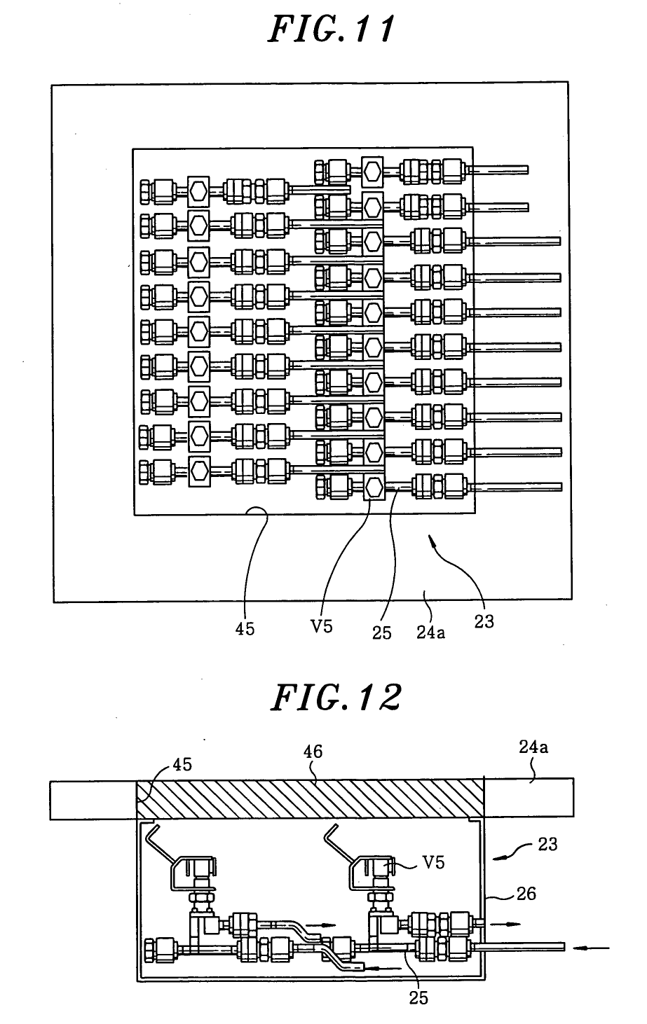

FIG. 11 is a top view showing the primary-side connection unit 23 employed in the apparatus shown in FIG. 9. FIG. 12 is a side elevational view illustrating the primary-side connection unit 23 shown in FIG. 11.

The floor panels 24 and 24a of the clean room are arranged lengthwise and crosswise with no gap left therebetween, each of which has a side of, e.g., about 600 mm in size. Support members 43 disposed at four corners of each of the floor panels 24 are adapted to support the respective floor panels 24 at a predetermined height from above a floor base 44. The primary-side connection unit 23 is attached underneath the floor panel 24a. The floor panel 24a having the primary-side connection unit 23 thereunder is placed at a preset position in place of the normal floor panel 24.

The primary-side connection unit 23 has a case 26 opened at its top. The case 26 is secured to the undersurface of the floor panel 24a. The floor panel 24a has an opening 45 that provides access to the primary-side connection unit 23. The opening 45 is closed by the openable cover 46, which seals the internal space of the case 26.

Accommodated within the case 26 are pipelines 25 which are respectively connected to a plurality of gas sources. Each of the pipelines 25 is arranged in such a manner that the inlet and the outlet end thereof are oriented in the same direction. The operator can manipulate valves V5 disposed on the pipelines 25 after opening the cover 46, so that the valves V5 may be a manually-operated valve. The pipelines 25 are connected to the flow rate control unit 13 in the gas box 14 through the trunk unit 28 having the gathered trunk pipelines 32 extending to below the floor panels 24 (see FIG. 9).

In accordance with the processing apparatus 1 of the second embodiment, the gas box 14 containing the flow rate control unit 13 is disposed underneath each of the processing chambers 2 and on the floor of the clean room. The flow rate control unit 13 is detachably coupled through the trunk unit 28 to the primary-side connection unit 23, which lies under the floor panel 24a at a position distant from the gas box 14. The floor panel 24a has the opening 45 that provides access to the primary-side connection unit 23 and the openable cover 46 closing the opening 45. The trunk unit 28 is disposed in place by attaching the case containing the trunk pipelines 32 to the underside of the floor panel 24.

With such arrangements, the operator can gain access to the primary-side connection unit 23 with ease, so that the maintainability thereof is improved. Furthermore, works can be done safely, thank to the fact that no pipeline or valve is disposed on the floor panels 24.

(Common Modification of First and Second Embodiments)

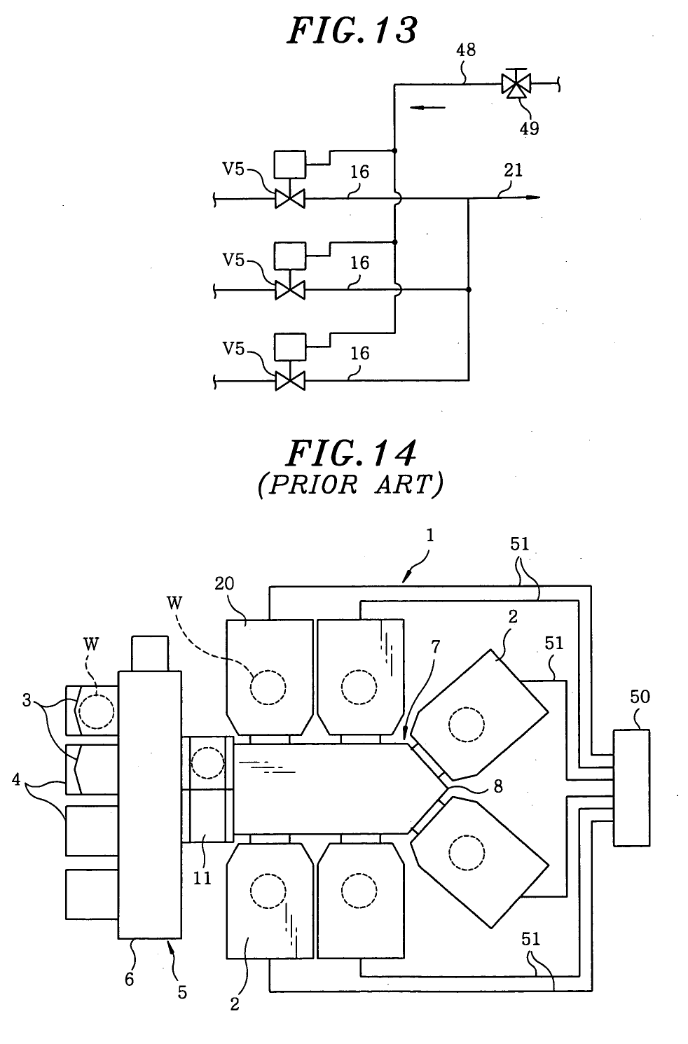

FIG. 13 is a piping diagram depicting a mechanism for concurrently closing switching valves of gas lines by a remote control operation, in a modification of the first and the second embodiment. For the sake of simplicity in illustration, the flow rate control unit 13 and the like are not shown in FIG. 13.

In case of conducting a maintenance for the processing apparatus 1, it is desirable that the valves (switching valves) V5 of the primary-side connection units 23 connected to all of the processing chambers 2 are in a closed condition from the viewpoint of safety. In the first embodiment, however, the valves V5 are hidden under the flow rate control unit 13 as illustrated in FIG. 4 and therefore cannot be manually operated with ease. Likewise, in the second embodiment, the valves V5 lie underneath the floor as can be seen in FIG. 12, which makes it necessary to open the cover 46 of the floor panel 24a prior to manipulating the valves V5.

In accordance with this modification, each of the valves V5 is a type operated by an air pressure and kept closed when no air pressure is applied thereto (a so-called normally-closed air operation valve). Further, a lock-out valve 49 that is a three-way valve of the type electrically operable and kept closed in a load-free condition (normally closed) is disposed on a common upstream line 48 through which the air is supplied to the valves V5.

As a result, when a maintenance work is carried out, all of the valves (switching valves) V5 can be concurrently closed through a remote control operation merely by closing off the lock-out valve 49 to cut off the air supply. Accordingly, by applying this modification to the first embodiment, it becomes possible to avoid the difficulty which would otherwise be encountered in manipulating the valves V5 hidden under the flow rate control unit 13. Further, by applying this modification to the second embodiment, there is no need to open the cover 46 of the floor panel 24a in an attempt to manipulate the valves V5.

Although the vacuum processing apparatus has been exemplified in the first and the second embodiment, the present invention may be equally applied to a normal pressure processing apparatus that performs a process under an atmospheric pressure. Moreover, the present invention may also be applied to other substrates than the semiconductor wafer, e.g., a glass substrate for a flat panel.

### INDUSTRIAL APPLICABILITY

In accordance with the semiconductor processing apparatus of the present invention, a process performance can be improved while a footprint can be reduced.

What is claimed is:

1. A semiconductor processing apparatus comprising:
a common transfer chamber;
a plurality of processing chambers, connected to the common transfer chamber, for processing a substrate;
a transfer mechanism, disposed within the common transfer chamber, for transferring the substrate with respect to the processing chambers; and
a plurality of gas supply systems for supplying predetermined gases, the gas supply systems being provided in the processing chambers, respectively,
wherein each of the gas supply systems includes:
a primary-side connection unit connected to gas sources of the predetermined gases, the primary-side connection unit being disposed underneath the corresponding one of the processing chambers;
a flow rate control unit for controlling flow rates of the predetermined gases, the flow rate control unit being disposed on gas lines through which the gases are supplied from the primary-side connection unit to the corresponding processing chamber, the flow rate control unit being disposed above the primary-side connection unit so as to at least partially overlap therewith; and
a gas box for enclosing the flow rate control unit, the gas box having a cover removably attached thereto for providing access to the flow rate control unit.

2. The apparatus of claim 1, wherein the primary-side connection unit and the flow rate control unit are detachably connected to each other through trunk pipelines constituting part of the gas lines.

3. The apparatus of claim 1, wherein the primary-side connection unit is disposed on a floor of a room in which the apparatus is installed.

4. The apparatus of claim 1, wherein the primary-side connection unit and the flow rate control unit are hermetically enclosed by the gas box.

5. The apparatus of claim 1, wherein the flow rate control unit is disposed to be inclined downwardly from an inner portion located above the primary-side connection unit toward an outer portion located in front of the primary-side connection unit.

6. The apparatus of claim 5, wherein the outer portion of the flow rate control unit is located out of a plan view contour of the corresponding processing chamber and wherein the cover constitutes at least part of front and top surfaces of the gas box.

7. The apparatus of claim 1, wherein the flow rate control unit is provided with a flow rate controller for monitoring pressures in the gas lines to control the flow rates of the predetermined gases, respectively.

8. The apparatus of claim 1, wherein the processing chambers are constructed to have a substantially same specification and the gas supply systems are constructed to have a substantially same specification, and wherein the distance between the flow rate control unit and the corresponding processing chamber is set to be equal between the gas supply systems.

9. The apparatus of claim 1, wherein each of the gas supply systems is provided with switching valves for opening and closing the respective gas lines, and the apparatus further comprises a remote control mechanism for concurrently closing the switching valves through a remote control operation.

10. The apparatus of claim 9, wherein each of the switching valves is a valve operated by an air pressure and kept closed when no air pressure is applied thereto, and the remote control mechanism is a lock-out valve disposed on a common upstream line through which an air is supplied to the switching valves.

11. A semiconductor processing apparatus comprising:
a common transfer chamber;
a plurality of processing chambers, connected to the common transfer chamber, for processing a substrate;
a transfer mechanism, disposed within the common transfer chamber, for transferring the substrate with respect to the processing chambers; and
a plurality of gas supply systems for supplying predetermined gases, the gas supply systems being provided in the processing chambers, respectively,
wherein each of the gas supply systems includes:
a primary-side connection unit connected to gas sources of the predetermined gases, the primary-side connection unit being disposed underneath a removable floor panel of a room in which the apparatus is installed, the floor panel having a cover which is detachable for providing access to the primary-side connection unit;
a flow rate control unit for controlling flow rates of the predetermined gases, the flow rate control unit being disposed on gas lines through which the gases are supplied from the primary-side connection unit to the corresponding one of the processing chambers, the flow rate control unit being disposed under the corresponding processing chamber such that at least a part thereof lies under the corresponding processing chamber; and
a gas box for enclosing the flow rate control unit, the gas box having a cover removably attached thereto for providing access to the flow rate control unit.

12. The apparatus of claim 11, wherein the primary-side connection unit and the flow rate control unit are detachably connected to each other through trunk pipelines constituting part of the gas lines.

13. The apparatus of claim 12, wherein the trunk pipelines are disposed underneath a floor panel of the room in which the apparatus is installed.

14. The apparatus of claim 11, wherein the flow rate control unit is hermetically enclosed by the gas box.

15. The apparatus of claim 11, wherein the flow rate control unit is disposed to be inclined downwardly from an inner portion thereof lying under the corresponding processing chamber toward an outer portion.

16. The apparatus of claim 15, wherein the outer portion of the flow rate control unit is located out of a plan view contour of the corresponding processing chamber and wherein the cover constitutes at least part of front and top surfaces of the gas box.

17. The apparatus of claim 11, wherein the flow rate control unit is provided with flow rate controllers for monitoring pressures in the gas lines to control the flow rates of the predetermined gases, respectively.

18. The apparatus of claim 11, wherein the processing chambers are constructed to have a substantially same specification and the gas supply systems are constructed to have a substantially same specification, and wherein the distance between the flow rate control unit and the corresponding processing chamber is set to be equal between the gas supply systems.

19. The apparatus of claim 11, wherein each of the gas supply systems is provided with switching valves for opening and closing the respective gas lines, and the apparatus further comprises a remote control mechanism for concurrently closing the switching valves through a remote control operation.

20. The apparatus of claim 19, wherein each of the switching valves is a valve operated by an air pressure and kept closed when no air pressure is applied thereto and wherein the remote control mechanism is a lock-out valve disposed on a common upstream line through which an air is supplied to the switching valves.
